(19) United States
(12) Patent Application Publication
(10) Pub. No.: US 2010/0327384 A1
(43) Pub. Date: Dec. 30, 2010

(54) SOLID-STATE IMAGE DEVICE

(75) Inventor: Naoki Tomoda, Shiga (JP)

Correspondence Address: HAMRE, SCHUMANN, MUELLER & LARSON P.C., P.O. BOX 2902, MINNEAPOLIS, MN, 55402-0902, US

(73) Assignee: PANASONIC CORPORATION, Osaka (JP)

(21) Appl. No.: 12/874,651

(22) Filed: Sep. 2, 2010

Related U.S. Application Data
(63) Continuation of application No. PCT/JP2009/001431, filed on Mar. 30, 2009.

(30) Foreign Application Priority Data
May 27, 2008 (JP) 2008-137348

(51) Int. Cl. H01L 31/0232

(52) U.S. Cl. 257/432; 257/E31.127

(57) ABSTRACT

Stacked filters are primary color filters and complementary color filters. Thus it is possible to suppress an increase in spectral characteristics and improve the color reproducibility of the primary color filters.

### FIELD OF THE INVENTION

The present invention relates to a solid-state image device provided with color filters.

### BACKGROUND OF THE INVENTION

In recent years, pixels in solid-state image devices have decreased in size and the sensitivity of solid-state image devices has considerably declined because of the size reduction. Thus in some cases, spectral colors through color filters are lightened to increase the output of received light.

A solid-state image device of the prior art will be described below in accordance with the accompanying drawings.

FIGS. 8A, 8B, 8C, 8D, and 8E are process sectional views showing a method of manufacturing the solid-state image device of the prior art. FIG. 9 shows the spectral characteristics of color filters in the solid-state image device of the prior art. FIG. 10 is a sectional view showing the configuration of the solid-state image device of the prior art in which a magenta filter, a yellow filter, and a cyan filter are used. FIGS. 11A and 113 show the spectral characteristics of the color filters in the solid-state image device of the prior art in which the magenta filter, the yellow filter, and the cyan filter are used. FIG. 11A shows the spectral characteristics of the complementary color filters alone. FIG. 11B shows the spectral characteristics of the stacked filters.

First, referring to FIGS. 8A, 8B, 8C, 8D, and 8E, the following will describe the method of manufacturing the solid-state image device according to the prior art in which spectral colors through the color filters are lightened.

As shown in FIG. 8A, acrylic resin is applied by spin coating over the uneven surface of a solid-state image element substrate 1 and light receiving portions 2 for converting incident light to an electric signal. After that, the acrylic resin is dried by heating to form an acrylic flat film 3.

Next, as shown in FIG. 8B, a color resist of green is applied by spin coating on the acrylic flat film 3, and then the color resist of green is irradiated with ultraviolet light including g-rays (wavelength of 436 nm) and i-rays (wavelength of 365 nm) to form a predetermined pattern with a photomask. Further, the color resist is patterned into separate pixels. After that, the color resist is dried by heating at 200° C. to 250° C. to form a green filter 4G.

Next, as shown in FIG. 8C, a color resist of blue is applied by spin coating on the acrylic flat film 3, and then the color resist of blue is irradiated with ultraviolet light including g-rays (wavelength of 436 nm) and i-rays (wavelength of 365 nm) to form a predetermined pattern with a photomask. Further, the color resist is patterned into separate pixels. After that, the color resist is dried by heating at 200° C. to 250° C. to form a blue filter 4B.

After that, as shown in FIG. 8D, a color resist of red is applied by spin coating on the acrylic flat film 3, and then the color resist of red is irradiated with ultraviolet light including g-rays (wavelength of 436 nm) and i-rays (wavelength of 365 nm) to form a predetermined pattern with a photomask. Further, the color resist is patterned into separate pixels. After that, the color resist is dried by heating at 200° C. to 250° C. to form a red filter 4R.

Finally, as shown in FIG. 8E, a synthetic resin film made of, e.g., acrylic resin is applied by spin coating over the color filters 4R, 4G, and 4B, and then the synthetic resin film is dried at low temperature. After that, the synthetic resin film is irradiated with ultraviolet light including g-rays (wavelength of 436 nm) and i-rays (wavelength of 365 nm) to form a predetermined pattern with a photomask. Further, the synthetic resin film is patterned into separate pixels. Next, the overall synthetic resin film is exposed to ultraviolet rays and the transmittance of an overall visible light region is improved to at least 90%. After that, heating and melting (reflow) are performed over the synthetic resin film and the synthetic resin film is thermally deformed such that each pixel has a dome shape projecting upward with a desired curvature, so that microlenses 5 are formed. The solid-state image device is manufactured thus.

FIG. 9 shows the spectral characteristics of the red filter 4R, the spectral characteristics of the green filter 4G, and the spectral characteristics of the blue filter 4B in the solid-state image device formed in FIGS. 8A, 8B, 8C, 8D, and 8E.

As shown in FIG. 9, in the characteristics of the red filter, a spectral ratio is increased in a short wavelength region around 400 nm to 450 nm. Further, in the characteristics of the blue filter, a spectral ratio is increased in a long wavelength region around 600 nm to 700 nm. The short wavelength region around 400 nm to 450 nm considerably affects the color reproducibility of blue and the long wavelength region around 600 nm to 700 nm considerably affects the color reproducibility of red. Thus disadvantageously, an increase in the characteristics of the red filter in the short wavelength region around 400 nm to 450 nm deteriorates the color reproducibility of blue, and an increase in the characteristics of the blue filter in the long wavelength region around 600 nm to 700 nm deteriorates the color reproducibility of red.

In a solution to this problem, as shown in FIG. 10, a red filter is formed by stacking a magenta filter 4M and a yellow filter 4Y and a blue filter is formed by stacking a magenta filter 4M and a cyan filter 4C. Generally, when filters are stacked, the spectral characteristics of the stacked filters are determined by a product at each wavelength in the spectral characteristics of the filters to be stacked. For this reason, in the case of the color filters formed by stacking the filters of FIG. 11A, as shown in FIG. 11B, an increase in the spectral characteristics of the red filter made up of the stacked filters is suppressed below an increase in the spectral characteristics of a single red filter in the short wavelength region around 400 nm to 450 nm, and an increase in the spectral characteristics of the blue filter made up of the stacked filters is suppressed below an increase in the spectral characteristics of a single blue filter in the long wavelength region around 600 nm to 700 nm (e.g., see Japanese Patent Laid-Open No. 2000-294758).

### DISCLOSURE OF THE INVENTION

However, in the configuration where the red filter is formed by complementary filters that are the magenta filter 4M and the yellow filter 4Y and the blue filter is formed by complementary filters that are the magenta filter 4M and the cyan filter 4C, it is not possible to satisfy the need for higher color reproducibility in recent years.

An object of a solid-state image device of the present invention is to improve the color reproducibility of primary color filters by suppressing a disadvantageous increase in the spectral characteristics of the red filter in a short wavelength region (around 400 nm to 450 nm) and a disadvantageous increase in the spectral characteristics of the blue filter in a long wavelength region (around 600 nm to 700 nm).

In order to attain the object, a solid-state image device of the present invention includes: a plurality of photodiodes formed on a solid-state image element substrate; a color filter used for reproducing red and formed on the photodiode receiving red light, out of the plurality of photodiodes; a color filter used for reproducing green and formed on the photodiode receiving green light, out of the plurality of photodiodes; and a color filter used for reproducing blue and formed on the photodiode receiving blue light, out of the plurality of photodiodes, wherein at least one of the color filter used for reproducing red, the color filter used for reproducing green, and the color filter used for reproducing blue is formed by stacking at least two of a red filter, a green filter, a blue filter, a cyan filter, and a yellow filter.

Further, the color filter used for reproducing red is formed by stacking the red filter and a first yellow filter, the color filter used for reproducing green is formed by stacking a second yellow filter and a first cyan filter, and the color filter used for reproducing blue is formed by stacking a second cyan filter and the blue filter.

The color filter used for reproducing red is formed by stacking the red filter and a first yellow filter, the color filter used for reproducing green is formed by stacking a second yellow filter and the cyan filter, and the color filter used for reproducing blue is formed by stacking the blue filter alone.

The color filter used for reproducing red is formed by stacking the red filter and the yellow filter, the color filter used for reproducing green is formed by stacking the green filter alone, and the color filter used for reproducing blue is formed by stacking the cyan filter and the blue filter.

The color filter used for reproducing red is formed by stacking the red filter and the yellow filter, the color filter used for reproducing green is formed by stacking the green filter alone, and the color filter used for reproducing blue is formed by stacking the blue filter alone.

The color filter used for reproducing red is formed by stacking the red filter alone, the color filter used for reproducing green is formed by stacking the green filter alone, and the color filter used for reproducing blue is formed by stacking the cyan filter and the blue filter.

The color filter used for reproducing red is formed by stacking the red filter alone, the color filter used for reproducing green is formed by stacking the yellow filter and a first cyan filter, and the color filter used for reproducing blue is formed by stacking a second cyan filter and the blue filter.

The first yellow filter and the second yellow filter are formed in the same layer.

The first cyan filter and the second cyan filter are formed in the same layer.

As previously mentioned, stacked filters are primary color filters and complementary color filters. Thus it is possible to suppress an increase in spectral characteristics and improve the color reproducibility of the primary color filters.

### BRIEF DESCRIPTION OF THE DRAWINGS

FIG. 1A is a process sectional view showing a method of manufacturing a solid-state image device according to a first embodiment;

FIG. 1B is a process sectional view showing the method of manufacturing the solid-state image device according to the first embodiment;

FIG. 1C is a process sectional view showing the method of manufacturing the solid-state image device according to the first embodiment;

FIG. 1D is a process sectional view showing the method of manufacturing the solid-state image device according to the first embodiment;

FIG. 1E is a process sectional view showing the method of manufacturing the solid-state image device according to the first embodiment;

FIG. 1F is a process sectional view showing the method of manufacturing the solid-state image device according to the first embodiment;

FIG. 2A shows spectral characteristics obtained in the solid-state image device according to the first embodiment;

FIG. 2B shows spectral characteristics obtained in the solid-state image device according to the first embodiment;

FIG. 3A is a process sectional view showing a method of manufacturing a solid-state image device according to a second embodiment;

FIG. 3B is a process sectional view showing the method of manufacturing the solid-state image device according to the second embodiment;

FIG. 3C is a process sectional view showing the method of manufacturing the solid-state image device according to the second embodiment;

FIG. 3D is a process sectional view showing the method of manufacturing the solid-state image device according to the second embodiment;

FIG. 3E is a process sectional view showing the method of manufacturing the solid-state image device according to the second embodiment;

FIG. 3F is a process sectional view showing the method of manufacturing the solid-state image device according to the second embodiment;

FIG. 4A is a process sectional view showing a method of manufacturing a solid-state image device according to a third embodiment;

FIG. 4B is a process sectional view showing the method of manufacturing the solid-state image device according to the third embodiment;

FIG. 4C is a process sectional view showing the method of manufacturing the solid-state image device according to the third embodiment;

FIG. 4D is a process sectional view showing the method of manufacturing the solid-state image device according to the third embodiment;

FIG. 4E is a process sectional view showing the method of manufacturing the solid-state image device according to the third embodiment;

FIG. 4F is a process sectional view showing the method of manufacturing the solid-state image device according to the third embodiment;

FIG. 4G is a process sectional view showing the method of manufacturing the solid-state image device according to the third embodiment;

FIG. 5A is a process sectional view showing a method of manufacturing a solid-state image device according to a fourth embodiment;

FIG. 5B is a process sectional view showing the method of manufacturing the solid-state image device according to the fourth embodiment;

FIG. 5C is a process sectional view showing the method of manufacturing the solid-state image device according to the fourth embodiment;

FIG. 5D is a process sectional view showing the method of manufacturing the solid-state image device according to the fourth embodiment;

FIG. 5E is a process sectional view showing the method of manufacturing the solid-state image device according to the fourth embodiment;

FIG. 5F is a process sectional view showing the method of manufacturing the solid-state image device according to the fourth embodiment;

FIG. 6A is a process sectional view showing a method of manufacturing a solid-state image device according to a fifth embodiment;

FIG. 6B is a process sectional view showing the method of manufacturing the solid-state image device according to the fifth embodiment;

FIG. 6C is a process sectional view showing the method of manufacturing the solid-state image device according to the fifth embodiment;

FIG. 6D is a process sectional view showing the method of manufacturing the solid-state image device according to the fifth embodiment;

FIG. 6E is a process sectional view showing the method of manufacturing the solid-state image device according to the fifth embodiment;

FIG. 6F is a process sectional view showing the method of manufacturing the solid-state image device according to the fifth embodiment;

FIG. 7A is a process sectional view showing a method of manufacturing a solid-state image device according to a sixth embodiment;

FIG. 7B is a process sectional view showing the method of manufacturing the solid-state image device according to the sixth embodiment;

FIG. 7C is a process sectional view showing the method of manufacturing the solid-state image device according to the sixth embodiment;

FIG. 7D is a process sectional view showing the method of manufacturing the solid-state image device according to the sixth embodiment;

FIG. 7E is a process sectional view showing the method of manufacturing the solid-state image device according to the sixth embodiment;

FIG. 7F is a process sectional view showing the method of manufacturing the solid-state image device according to the sixth embodiment;

FIG. 8A is a process sectional view showing a method of manufacturing a solid-state image device of the prior art;

FIG. 8B is a process sectional view showing the method of manufacturing the solid-state image device of the prior art;

FIG. 8C is a process sectional view showing the method of manufacturing the solid-state image device of the prior art;

FIG. 8D is a process sectional view showing the method of manufacturing the solid-state image device of the prior art;

FIG. 8E is a process sectional view showing the method of manufacturing the solid-state image device of the prior art;

FIG. 9 shows the spectral characteristics of color filters in the solid-state image device of the prior art;

FIG. 10 is a sectional view showing the configuration of a solid-state image device in which a magenta filter, a yellow filter, and a cyan filter are used according to the prior art;

FIG. 11A shows the spectral characteristics of the color filters in the solid-state image device in which the magenta filter, the yellow filter, and the cyan filter are used according to the prior art; and

FIG. 11B shows the spectral characteristics of the color filters in the solid-state image device in which the magenta filter, the yellow filter, and the cyan filter are used according to the prior art.

### DESCRIPTION OF THE EMBODIMENTS

### First Embodiment

A solid-state image device according to a first embodiment of the present invention will be described below in accordance with the accompanying drawings.

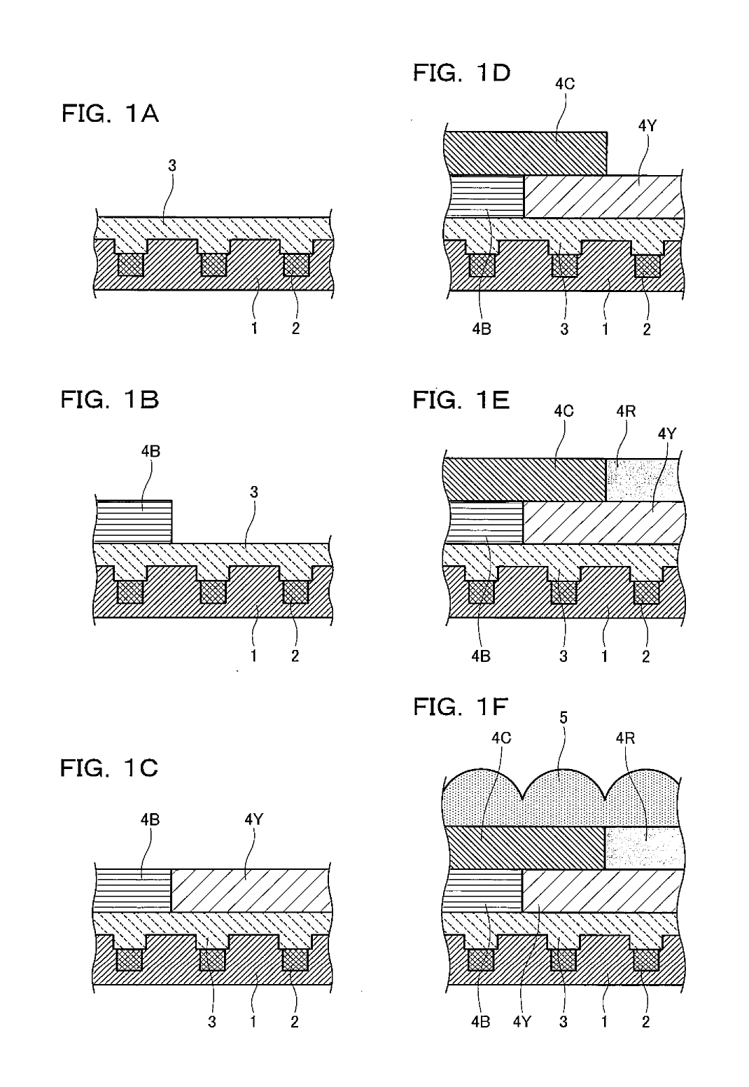

FIGS. 1A, 1B, 1C, 1D, 1E, and 1F are process sectional views showing a method of manufacturing the solid-state image device according to the first embodiment.

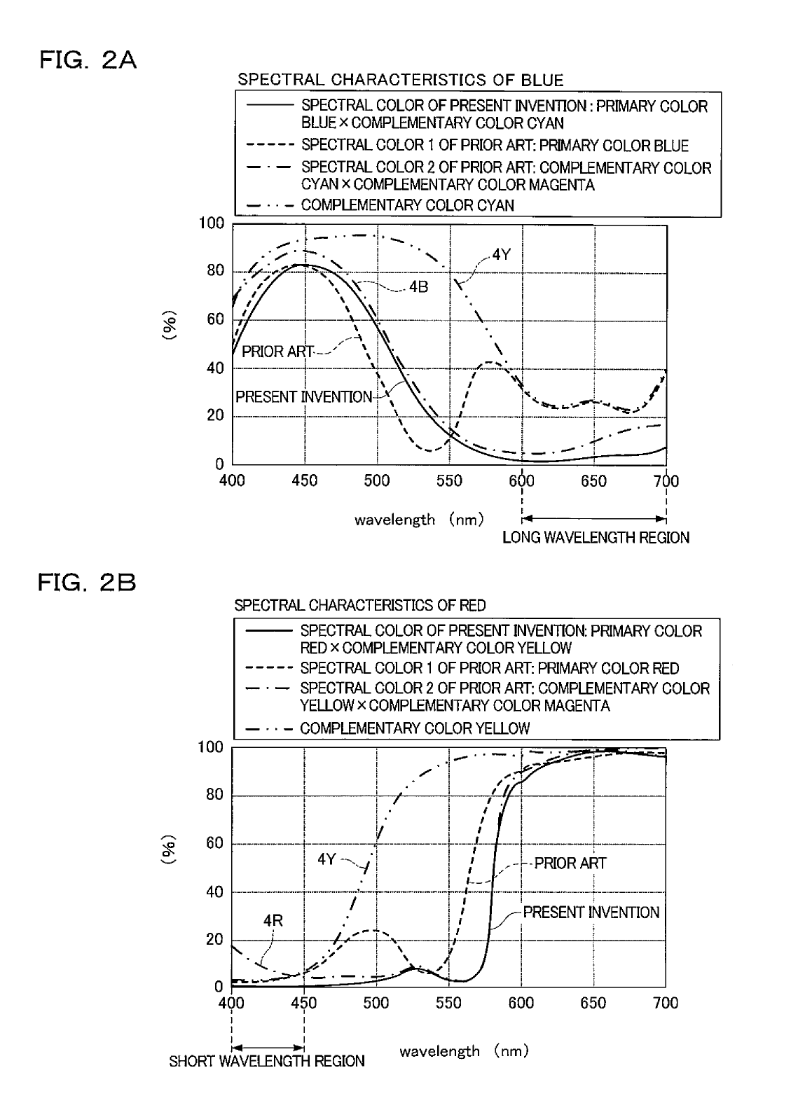

FIGS. 2A and 2B show the spectral characteristics of the solid-state image device according to the first embodiment. FIG. 2A shows the spectral characteristics of blue and FIG. 2B shows the spectral characteristics of red.

As shown in FIG. 1F, the solid-state image device is made up of a solid-state image element substrate 1; a plurality of light receiving portions 2 that are photodiodes formed in the solid-state image element substrate 1; an acrylic flat film 3 formed on the light receiving portions 2; a blue filter 4B and a yellow filter 4Y that are formed on the acrylic flat film 3; a cyan filter 4C formed on the blue filter 4B and the yellow filter 4Y; a red filter 4R formed on the yellow filter 4Y; and a plurality of microlenses 5 that are placed above the respective light receiving portions 2 and condense incident light onto the light receiving portions 2 placed below the respective microlenses 5. In the solid-state image device, it is necessary to reproduce primary colors that are red, green, and blue. The cyan filter 4C is stacked on the blue filter 4B to reproduce blue, the cyan filter 4C is stacked on the yellow filter 4Y to reproduce green, and the red filter 4R is stacked on the yellow filter 4Y to reproduce red.

In this configuration, the blue filter 4B and the cyan filter 4C are stacked to reproduce blue. Thus as shown in FIG. 2A, the spectral characteristics of the stacked filters are determined by the spectral characteristics of the blue filter 4B and the cyan filter 4C and it is possible to suppress an increase in the spectral characteristics of blue of the stacked color filters in a long wavelength region around 600 nm to 700 nm where the spectral characteristics of blue considerably affect the spectral characteristics of red, as compared with the case where the yellow filter 4Y is stacked on a magenta filter 4M to reproduce blue. It is therefore possible to improve the color reproducibility of red.

Further, the red filter 4R is stacked on the yellow filter 4Y to reproduce red. Thus as shown in FIG. 2B, the spectral characteristics of the stacked filters are determined by the spectral characteristics of the yellow filter 4Y and the red filter 4R and it is possible to suppress an increase in the spectral characteristics of red of the stacked color filters in a short wavelength region around 400 nm to 450 nm where the spectral characteristics of red considerably affect the spectral characteristics of blue, as compared with the case where the cyan filter 4C is stacked on the magenta filter 4M to reproduce red. It is therefore possible to improve the color reproducibility of blue.

FIGS. 1A, 1B, 1C, 1D, 1E, and 1F show a method of forming the solid-state image device according to the present embodiment.

As shown in FIG. 1A, acrylic resin is applied by spin coating over the uneven surface of a layer made up of the solid-state image element substrate 1 and the light receiving portions 2 for converting incident light into an electric signal, and then the acrylic resin is dried by heating to form the acrylic flat film 3.

Next, as shown in FIG. 1B, a color resist of blue is applied by spin coating with a thickness of 0.5 μm to 2.0 μm on the acrylic flat film 3. After that, the color resist of blue is irradiated with ultraviolet light including g-rays (wavelength of 436 nm) and i-rays (wavelength of 365 nm) to form a blue pixel pattern with a photomask. Further, the color resist is patterned in a divided manner and then is dried by heating at 200° C. to 250° C. to form the blue filter 4B.

Next, as shown in FIG. 1C, a color resist of yellow is applied by spin coating with a thickness of 0.5 μm to 2.0 μm on the acrylic flat film 3 and the blue filter 4B. After that, the color resist of yellow is irradiated with ultraviolet light including g-rays (wavelength of 436 nm) and i-rays (wavelength of 365 nm) to form green and red pixel patterns with a photomask. Further, the color resist is patterned in a divided manner and then is dried by heating at 200° C. to 250° C. to form the yellow filter 4Y. At this point, the yellow filter 4Y is desirably as thick as the blue filter 4B.

Next, as shown in FIG. 1D, a color resist of cyan is applied by spin coating with a thickness of 0.5 μm to 2.0 μm on the blue filter 4B and the yellow filter 4Y. After that, the color resist of cyan is irradiated with ultraviolet light including g-rays (wavelength of 436 nm) and i-rays (wavelength of 365 nm) to form blue and green pixel patterns with a photomask. Further, the color resist is patterned in a divided manner and then is dried by heating at 200° C. to 250° C. to form the cyan filter 4C.

Next, as shown in FIG. 1E, a color resist of red is applied by spin coating with a thickness of 0.5 μm to 2.0 μm on the cyan filter 4C and the yellow filter 4Y. After that, the color resist of red is irradiated with ultraviolet light including g-rays (wavelength of 436 nm) and i-rays (wavelength of 365 nm) to form a red pixel pattern with a photomask. Further, the color resist is patterned in a divided manner and then is dried by heating at 200° C. to 250° C. to form the red filter 4R. At this point, the red filter 4R is desirably as thick as the cyan filter 4C.

In this case, the color resist may be one of a negative resist and a positive resist or one of a pigment resist and a dye resist.

The color filters may be formed in any order as long as the primary blue filter 4B and the complementary cyan filter 4C are stacked on top of each other, the complementary yellow filter 4Y and the complementary cyan filter 4C are stacked on top of each other, and the primary red filter 4R and the complementary yellow filter 4Y are stacked on top of each other.

The present embodiment described an example in which the yellow filter used for reproducing green and the yellow filter used for reproducing red are formed at the same time. The yellow filters may be separately formed.

Next, as shown in FIG. 1F, a synthetic resin film made of, e.g., acrylic resin is applied by spin coating over the cyan filter 4C and the red filter 4R and then is dried at low temperature. The synthetic resin film is irradiated with ultraviolet light including g-rays (wavelength of 436 nm) and i-rays (wavelength of 365 nm) to form a predetermined pattern with a photomask. Further, the synthetic resin film is patterned into separate pixels. Next, the overall synthetic resin film is exposed to ultraviolet rays and the transmittance of an overall visible light region is improved to at least 90%. After that, heating and melting (reflow) are performed over the synthetic resin film and the synthetic resin film is thermally deformed into dome shapes, each projecting upward with a desired curvature, so that the microlenses 5 are formed.

### Second Embodiment

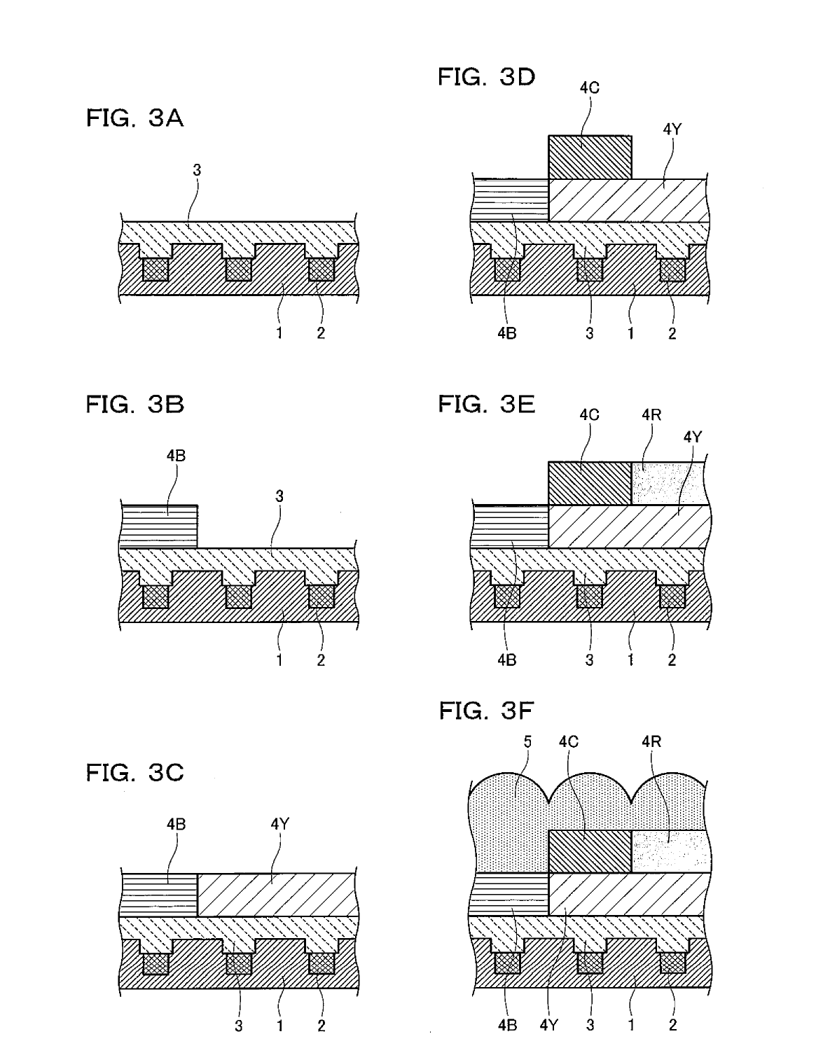

FIGS. 3A, 3B, 3C, 3D, 3E, and 3F are process sectional views showing a method of manufacturing a solid-state image device according to a second embodiment.

As shown in FIG. 3F, the solid-state image device is made up of a solid-state image element substrate 1; a plurality of light receiving portions 2 that are photodiodes formed in the solid-state image element substrate 1; an acrylic flat film 3 formed on the light receiving portions 2; a blue filter 4B and a yellow filter 4Y that are formed on the acrylic flat film 3; a cyan filter 4C formed on the yellow filter 4Y; a red filter 4R formed on the yellow filter 4Y; and a plurality of microlenses 5 that are placed above the respective light receiving portions 2 and condense incident light onto the light receiving portions 2 placed below the respective microlenses 5. In the solid-state image device, it is necessary to reproduce primary colors that are red, green, and blue. The blue filter 4B is formed alone to reproduce blue, the cyan filter 4C is stacked on the yellow filter 4Y to reproduce green, and the red filter 4R is stacked on the yellow filter 4Y to reproduce red.

In this configuration, the yellow filter 4Y and the red filter 4R are stacked to reproduce red. Thus as shown in FIG. 2B, the spectral characteristics of the stacked filters are determined by the spectral characteristics of the yellow filter 4Y and the red filter 4R and it is possible to suppress an increase in the spectral characteristics of red of the stacked color filters in a short wavelength region around 400 nm to 450 nm where the spectral characteristics of red considerably affect the spectral characteristics of blue, as compared with the case where the cyan filter 4C is stacked on a magenta filter 4M to reproduce red. It is therefore possible to improve the color reproducibility of blue.

FIGS. 3A, 3B, 3C, 3D, 3E, and 3F show a method of forming the solid-state image device according to the present embodiment.

As shown in FIG. 3A, acrylic resin is applied by spin coating over the uneven surface of a layer made up of the solid-state image element substrate 1 and the light receiving portions 2 for converting incident light into an electric signal, and then the acrylic resin is dried by heating to form the acrylic flat film 3.

Next, as shown in FIG. 3B, a color resist of blue is applied by spin coating with a thickness of 0.5 μm to 2.0 μm on the acrylic flat film 3. After that, the color resist of blue is irradiated with ultraviolet light including g-rays (wavelength of 436 nm) and i-rays (wavelength of 365 nm) to form a blue pixel pattern with a photomask. Further, the color resist is patterned in a divided manner and then is dried by heating at 200° C. to 250° C. to form the blue filter 4B.

Next, as shown in FIG. 3C, a color resist of yellow is applied by spin coating with a thickness of 0.5 μm to 2.0 μm on the acrylic flat film 3 and the blue filter 4B. After that, the color resist of yellow is irradiated with ultraviolet light including g-rays (wavelength of 436 nm) and i-rays (wavelength of 365 nm) to form green and red pixel patterns with a photomask. Further, the color resist is patterned in a divided manner and then is dried by heating at 200° C. to 250° C. to form the yellow filter 4Y. At this point, the yellow filter 4Y is desirably as thick as the blue filter 4B.

Next, as shown in FIG. 3D, a color resist of cyan is applied by spin coating with a thickness of 0.5 μn to 2.0 μm on the blue filter 4B and the yellow filter 4Y. After that, the color resist of cyan is irradiated with ultraviolet light including g-rays (wavelength of 436 nm) and i-rays (wavelength of 365 nm) to form a green pixel pattern with a photomask. Further, the color resist is patterned in a divided manner and then is dried by heating at 200° C. to 250° C. to form the cyan filter 4C.

Next, as shown in FIG. 3E, a color resist of red is applied by spin coating with a thickness of 0.5 μm to 2.0 μm on the blue filter 4B, the cyan filter 4C, and the yellow filter 4Y. After that, the color resist of red is irradiated with ultraviolet light including g-rays (wavelength of 436 nm) and i-rays (wavelength of 365 nm) to form a red pixel pattern with a photomask. Further, the color resist is patterned in a divided manner and then is dried by heating at 200° C. to 250° C. to form the red filter 4R. At this point, the red filter 4R is desirably as thick as the cyan filter 4C.

In this case, the color resist may be one of a negative resist and a positive resist or one of a pigment resist and a dye resist.

The color filters may be formed in any order as long as the complementary yellow filter 4Y and the complementary cyan filter 4C are stacked on top of each other and the primary red filter 4R and the complementary yellow filter 4Y are stacked on top of each other.

The present embodiment described an example in which the yellow filter used for reproducing green and the yellow filter used for reproducing red are formed at the same time. The yellow filters may be separately formed.

Finally, as shown in FIG. 3F, a synthetic resin film made of, e.g., acrylic resin is applied by spin coating over the blue filter 4B, the cyan filter 4C, and the red filter 4R and then is dried at low temperature. After that, the synthetic resin film is irradiated with ultraviolet light including g—rays (wavelength of 436 nm) and i-rays (wavelength of 365 nm) to form a predetermined pattern with a photomask. Further, the synthetic resin film is patterned into separate pixels. Next, the overall synthetic resin film is exposed to ultraviolet rays and the transmittance of an overall visible light region is improved to at least 90%. After that, heating and melting (reflow) are performed over the synthetic resin film and the synthetic resin film is thermally deformed into dome shapes, each projecting upward with a desired curvature, so that the microlenses 5 are formed.

### Third Embodiment

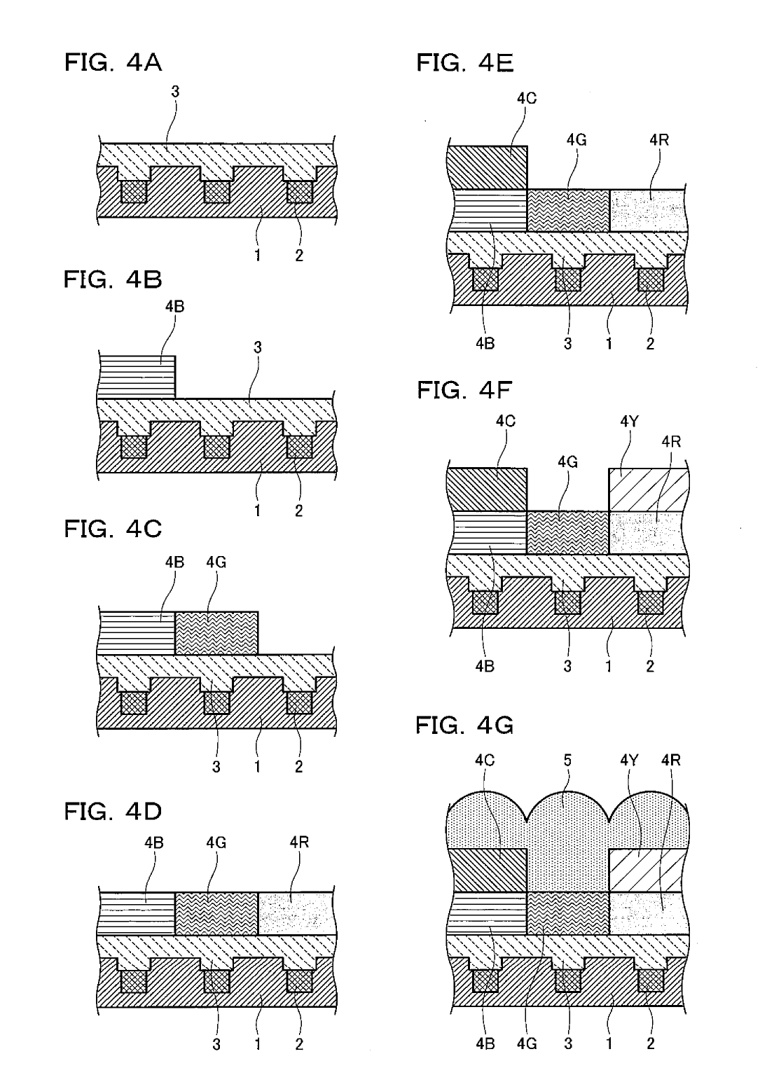

FIGS. 4A, 4B, 4C, 4D, 4E, 4F, and 4G are process sectional views showing a method of manufacturing a solid-state image device according to a third embodiment.

As shown in FIG. 4G, the solid-state image device is made up of a solid-state image element substrate 1; a plurality of light receiving portions 2 that are photodiodes formed in the solid-state image element substrate 1; an acrylic flat film 3 formed on the light receiving portions 2; a blue filter 4B, a green filter 4G, and a red filter 4R that are formed on the acrylic flat film 3; a cyan filter 4C formed on the blue filter 4B; a yellow filter 4Y formed on the red filter 4R; and a plurality of microlenses 5 that are placed above the respective light receiving portions 2 and condense incident light onto the light receiving portions 2 placed below the respective microlenses 5. In the solid-state image device, it is necessary to reproduce primary colors that are red, green, and blue. The cyan filter 4C is stacked on the blue filter 4B to reproduce blue, the green filter 4G is formed alone to reproduce green, and the yellow filter 4Y is stacked on the red filter 4R to reproduce red.

In this configuration, the blue filter 4B and the cyan filter 4C are stacked to reproduce blue. Thus as shown in FIG. 2A, the spectral characteristics of the stacked filters are determined by the spectral characteristics of the blue filter 4B and the cyan filter 4C and it is possible to suppress an increase in the spectral characteristics of blue of the stacked color filters in a long wavelength region around 600 nm to 700 nm where the spectral characteristics of blue considerably affect the spectral characteristics of red, as compared with the case where the yellow filter 4Y is stacked on a magenta filter 4M to reproduce blue. It is therefore possible to improve the color reproducibility of red.

Further, the yellow filter 4Y and the red filter 4R are stacked to reproduce red. Thus as shown in FIG. 2B, the spectral characteristics of the stacked filters are determined by the spectral characteristics of the yellow filter 4Y and the red filter 4R and it is possible to suppress an increase in the spectral characteristics of red of the stacked color filters in a short wavelength region around 400 nm to 450 nm where the spectral characteristics of red considerably affect the spectral characteristics of blue, as compared with the case where the cyan filter 4C is stacked on the magenta filter 4M to reproduce red. It is therefore possible to improve the color reproducibility of blue.

FIGS. 4A, 4B, 4C, 4D, 4E, 4F, and 4G show a method of forming the solid-state image device according to the present embodiment.

As shown in FIG. 4A, acrylic resin is applied by spin coating over the uneven surface of a layer made up of the solid-state image element substrate 1 and the light receiving portions 2 for converting incident light into an electric signal, and then the acrylic resin is dried by heating to form the acrylic flat film 3.

Next, as shown in FIG. 4B, a color resist of blue is applied by spin coating with a thickness of 0.5 μm to 2.0 μm on the acrylic flat film 3. After that, the color resist of blue is irradiated with ultraviolet light including g-rays (wavelength of 436 nm) and i-rays (wavelength of 365 nm) to form a blue pixel pattern with a photomask. Further, the color resist is patterned in a divided manner and then is dried by heating at 200° C. to 250° C. to form the blue filter 4B.

Next, as shown in FIG. 4C, a color resist of green is applied by spin coating with a thickness of 0.5 μm to 2.0 μm on the acrylic flat film 3 and the blue filter 4B. After that, the color resist of green is irradiated with ultraviolet light including g-rays (wavelength of 436 nm) and i-rays (wavelength of 365 nm) to form a green pixel pattern with a photomask. Further, the color resist is patterned in a divided manner and then is dried by heating at 200° C. to 250° C. to form the green filter 4G. At this point, the green filter 4G is desirably as thick as the blue filter 4B.

Next, as shown in FIG. 4D, a color resist of red is applied by spin coating with a thickness of 0.5 μm to 2.0 μm on the acrylic flat film 3, the blue filter 4B, and the green filter 4G. After that, the color resist of red is irradiated with ultraviolet light including g-rays (wavelength of 436 nm) and i-rays (wavelength of 365 nm) to form a red pixel pattern with a photomask. Further, the color resist is patterned in a divided manner and then is dried by heating at 200° C. to 250° C. to form the red filter 4R. At this point, the red filter 4R is desirably as thick as the blue filter 4B and the green filter 4G.

Next, as shown in FIG. 4E, a color resist of cyan is applied by spin coating with a thickness of 0.5 μm to 2.0 μm on the blue filter 4B, the green filter 4G, and the red filter 4R. After that, the color resist of cyan is irradiated with ultraviolet light including g-rays (wavelength of 436 nm) and i-rays (wavelength of 365 nm) to form a blue pixel pattern with a photomask. Further, the color resist is patterned in a divided manner and then is dried by heating at 200° C. to 250° C. to form the cyan filter 4C.

Next, as shown in FIG. 4F, a color resist of yellow is applied by spin coating with a thickness of 0.5 μm to 2.0 μm on the cyan filter 4C, the green filter 4G, and the red filter 4R. After that, the color resist of yellow is irradiated with ultraviolet light including g-rays (wavelength of 436 nm) and i-rays (wavelength of 365 nm) to form a red pixel pattern with a photomask. Further, the color resist is patterned in a divided manner and then is dried by heating at 200° C. to 250° C. to form the yellow filter 4Y. At this point, the yellow filter 4Y is desirably as thick as the cyan filter 4C.

The color resist may be one of a negative resist and a positive resist or one of a pigment resist and a dye resist.

The color filters may be formed in any order as long as the primary blue filter 4B and the complementary cyan filter 4C are stacked on top of each other and the primary red filter 4R and the complementary yellow filter 4Y are stacked on top of each other.

Finally, as shown in FIG. 4G, a synthetic resin film made of, e.g., acrylic resin is applied by spin coating over the cyan filter 4C, the green filter 4G, and the yellow filter 4Y, and then the synthetic resin film is dried at low temperature. After that, the synthetic resin film is irradiated with ultraviolet light including g-rays (wavelength of 436 nm) and i-rays (wavelength of 365 nm) to form a predetermined pattern with a photomask. Further, the synthetic resin film is patterned into separate pixels. Next, the overall synthetic resin film is exposed to ultraviolet rays and the transmittance of an overall visible light region is improved to at least 90%. After that, heating and melting (reflow) are performed over the synthetic resin film and the synthetic resin film is thermally deformed into dome shapes, each projecting upward with a desired curvature, so that the microlenses 5 are formed.

### Fourth Embodiment

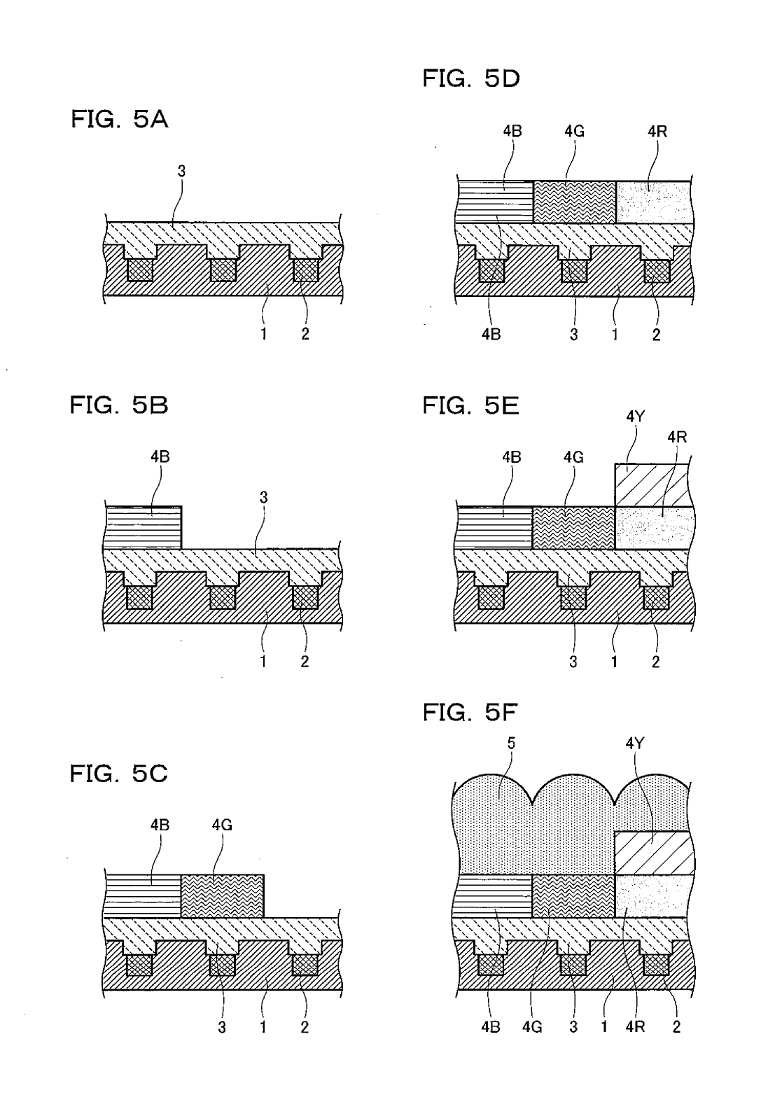

FIGS. 5A, 5B, 5C, 5D, 5E, and 5F are process sectional views showing a method of manufacturing a solid-state image device according to a fourth embodiment.

As shown in FIG. 5F, the solid-state image device is made up of a solid-state image element substrate 1; a plurality of light receiving portions 2 that are photodiodes formed in the solid-state image element substrate 1; an acrylic flat film 3 formed on the light receiving portions 2; a blue filter 4B, a green filter 4G, and a red filter 4R that are formed on the acrylic flat film 3; a yellow filter 4Y formed on the red filter 4R; and a plurality of microlenses 5 that are placed above the respective light receiving portions 2 and condense incident light onto the light receiving portions 2 placed below the respective microlenses 5. In the solid-state image device, it is necessary to reproduce primary colors that are red, green, and blue. The blue filter 4B is formed alone to reproduce blue, the green filter 4G is formed alone to reproduce green, and the yellow filter 4Y is stacked on the red filter 4R to reproduce red.

In this configuration, the yellow filter 4Y and the red filter 4R are stacked to reproduce red. Thus as shown in FIG. 2B, the spectral characteristics of the stacked filters are determined by the spectral characteristics of the yellow filter 4Y and the red filter 4R and it is possible to suppress an increase in the spectral characteristics of red of the stacked color filters in a short wavelength region around 400 nm to 450 nm where the spectral characteristics of red considerably affect the spectral characteristics of blue, as compared with the case where the cyan filter 4C is stacked on the magenta filter 4M to reproduce red. It is therefore possible to improve the color reproducibility of blue.

FIGS. 5A, 5B, 5C, 5D, 5E, and 5F show a method of forming the solid-state image device according to the present embodiment.

As shown in FIG. 5A, acrylic resin is applied by spin coating over the uneven surface of a layer made up of the solid-state image element substrate 1 and the light receiving portions 2 for converting incident light into an electric signal, and then the acrylic resin is dried by heating to form the acrylic flat film 3.

Next, as shown in FIG. 5B, a color resist of blue is applied by spin coating with a thickness of 0.5 μm to 2.0 μm on the acrylic flat film 3. After that, the color resist of blue is irradiated with ultraviolet light including g-rays (wavelength of 436 nm) and i-rays (wavelength of 365 nm) to form a blue pixel pattern with a photomask. Further, the color resist is patterned in a divided manner and then is dried by heating at 200° C. to 250° C. to form the blue filter 4B.

Next, as shown in FIG. 5C, a color resist of green is applied by spin coating with a thickness of 0.5 μm to 2.0 μm on the acrylic flat film 3 and the blue filter 4B. After that, the color resist of green is irradiated with ultraviolet light including g-rays (wavelength of 436 nm) and i-rays (wavelength of 365 nm) to form a green pixel pattern with a photomask. Further, the color resist is patterned in a divided manner and then is dried by heating at 200° C. to 250° C. to form the green filter 4G. At this point, the green filter 4G is desirably as thick as the blue filter 4B.

Next, as shown in FIG. 5D, a color resist of red is applied by spin coating with a thickness of 0.5 μm to 2.0 μm on the acrylic flat film 3, the blue filter 4B, and the green filter 4G. After that, the color resist of red is irradiated with ultraviolet light including g-rays (wavelength of 436 nm) and i-rays (wavelength of 365 nm) to form a red pixel pattern with a photomask. Further, the color resist is patterned in a divided manner and then is dried by heating at 200° C. to 250° C. to form the red filter 4R. At this point, the red filter 4R is desirably as thick as the blue filter 4B and the green filter 4G.

Next, as shown in FIG. 5E, a color resist of yellow is applied by spin coating with a thickness of 0.5 μm to 2.0 μm on the blue filter 4B, the green filter 4G, and the red filter 4R. After that, the color resist of yellow is irradiated with ultraviolet light including g-rays (wavelength of 436 nm) and i-rays (wavelength of 365 nm) to form a red pixel pattern with a photomask. Further, the color resist is patterned in a divided manner and then is dried by heating at 200° C. to 250° C. to form the yellow filter 4Y.

The color resist may be one of a negative resist and a positive resist or one of a pigment resist and a dye resist.

The color filters may be formed in any order as long as the primary red filter 4R and the complementary yellow filter 4Y are stacked on top of each other.

Finally, as shown in FIG. 5F, a synthetic resin film made of, e.g., acrylic resin is applied by spin coating over the blue filter 4B, the green filter 4G, and the yellow filter 4Y, and then the synthetic resin film is dried at low temperature. After that, the synthetic resin film is irradiated with ultraviolet light including g-rays (wavelength of 436 nm) and i-rays (wavelength of 365 nm) to form a predetermined pattern with a photomask. Further, the synthetic resin film is patterned into separate pixels. Next, the overall synthetic resin film is exposed to ultraviolet rays and the transmittance of an overall visible light region is improved to at least 90%. After that, heating and melting (reflow) are performed over the synthetic resin film and the synthetic resin film is thermally deformed into dome shapes, each projecting upward with a desired curvature, so that the microlenses 5 are formed.

### Fifth Embodiment

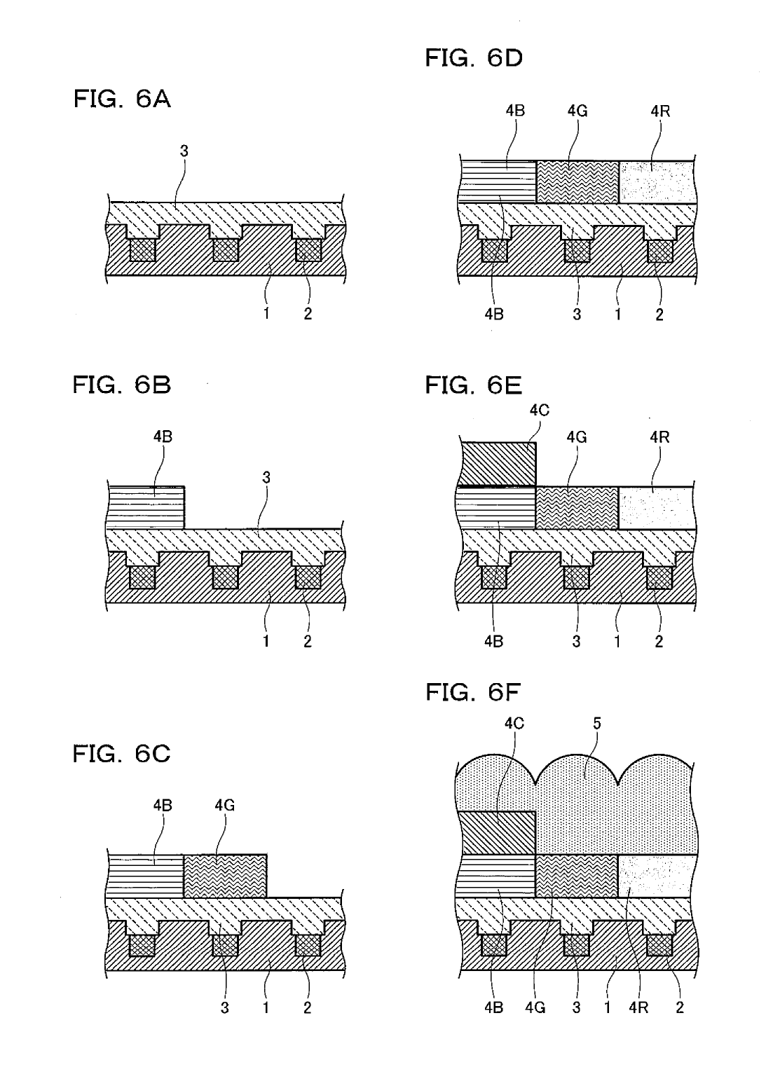

FIGS. 6A, 6B, 6C, 6D, 6E, and 6F are process sectional views showing a method of manufacturing a solid-state image device according to a fifth embodiment.

As shown in FIG. 6F, the solid-state image device is made up of a solid-state image element substrate 1; a plurality of light receiving portions 2 that are photodiodes formed in the solid-state image element substrate 1; an acrylic flat film 3 formed on the light receiving portions 2; a blue filter 4B, a green filter 4G, and a red filter 4R that are formed on the acrylic flat film 3; a cyan filter 4C formed on the blue filter 4B; and a plurality of microlenses 5 that are placed above the respective light receiving portions 2 and condense incident light onto the light receiving portions 2 placed below the respective microlenses 5. In the solid-state image device, it is necessary to reproduce primary colors that are red, green, and blue. The cyan filter 4C is stacked on the blue filter 4B to reproduce blue, the green filter 4G is formed alone to reproduce green, and the red filter 4R is formed alone to reproduce red.

In this configuration, the blue filter 4B and the cyan filter 4C are stacked to reproduce blue. Thus as shown in FIG. 2A, the spectral characteristics of the stacked filters are determined by the spectral characteristics of the blue filter 4B and the cyan filter 4C and it is possible to suppress an increase in the spectral characteristics of blue of the stacked color filters in a long wavelength region around 600 nm to 700 nm where the spectral characteristics of blue considerably affect the spectral characteristics of red, as compared with the case where the yellow filter 4Y is stacked on a magenta filter 4M to reproduce blue. It is therefore possible to improve the color reproducibility of red.

FIGS. 6A, 6B, 6C, 6D, 6E, and 6F show a method of forming the solid-state image device according to the present embodiment.

As shown in FIG. 6A, acrylic resin is applied by spin coating over the uneven surface of a layer made up of the solid-state image element substrate 1 and the light receiving portions 2 for converting incident light into an electric signal, and then the acrylic resin is dried by heating to form the acrylic flat film 3.

Next, as shown in FIG. 6B, a color resist of blue is applied by spin coating with a thickness of 0.5 μm to 2.0 μm on the acrylic flat film 3. After that, the color resist of blue is irradiated with ultraviolet light including g-rays (wavelength of 436 nm) and i-rays (wavelength of 365 nm) to form a blue pixel pattern with a photomask. Further, the color resist is patterned in a divided manner and then is dried by heating at 200° C. to 250° C. to form the blue filter 4B.

Next, as shown in FIG. 6C, a color resist of green is applied by spin coating with a thickness of 0.5 μm to 2.0 μm on the acrylic flat film 3 and the blue filter 4B. After that, the color resist of green is irradiated with ultraviolet light including g-rays (wavelength of 436 nm) and i-rays (wavelength of 365 nm) to form a green pixel pattern with a photomask. Further, the color resist is patterned in a divided manner and then is dried by heating at 200° C. to 250° C. to form the green filter 4G. At this point, the green filter 4G is desirably as thick as the blue filter 4B.

Next, as shown in FIG. 6D, a color resist of red is applied by spin coating with a thickness of 0.5 μm to 2.0 μm on the acrylic flat film 3, the blue filter 4B, and the green filter 4G. After that, the color resist of red is irradiated with ultraviolet light including g-rays (wavelength of 436 nm) and i-rays (wavelength of 365 nm) to form a red pixel pattern with a photomask. Further, the color resist is patterned in a divided manner and then is dried by heating at 200° C. to 250° C. to form the red filter 4R. At this point, the red filter 4R is desirably as thick as the blue filter 4B and the green filter 4G.

Next, as shown in FIG. 6E, a color resist of cyan is applied by spin coating with a thickness of 0.5 μm to 2.0 μm on the blue filter 4B, the green filter 4G, and the red filter 4R. After that, the color resist of cyan is irradiated with ultraviolet light including g-rays (wavelength of 436 nm) and i-rays (wavelength of 365 nm) to form a blue pixel pattern with a photomask. Further, the color resist is patterned in a divided manner and then is dried by heating at 200° C. to 250° C. to form the cyan filter 4C.

The color resist may be one of a negative resist and a positive resist or one of a pigment resist and a dye resist.

The color filters may be formed in any order as long as the primary blue filter 4B and the complementary cyan filter 4C are stacked on top of each other.

Finally, as shown in FIG. 6F, a synthetic resin film made of, e.g., acrylic resin is applied by spin coating over the cyan filter 4C, the green filter 4G, and the red filter 4R, and then the synthetic resin film is dried at low temperature. After that, the synthetic resin film is irradiated with ultraviolet light including g-rays (wavelength of 436 nm) and i-rays (wavelength of 365 nm) to form a predetermined pattern with a photomask. Further, the synthetic resin film is patterned into separate pixels. Next, the overall synthetic resin film is exposed to ultraviolet rays and the transmittance of an overall visible light region is improved to at least 90%. After that, heating and melting (reflow) are performed over the synthetic resin film and the synthetic resin film is thermally deformed into dome shapes, each projecting upward with a desired curvature, so that the microlenses 5 are formed.

### Sixth Embodiment

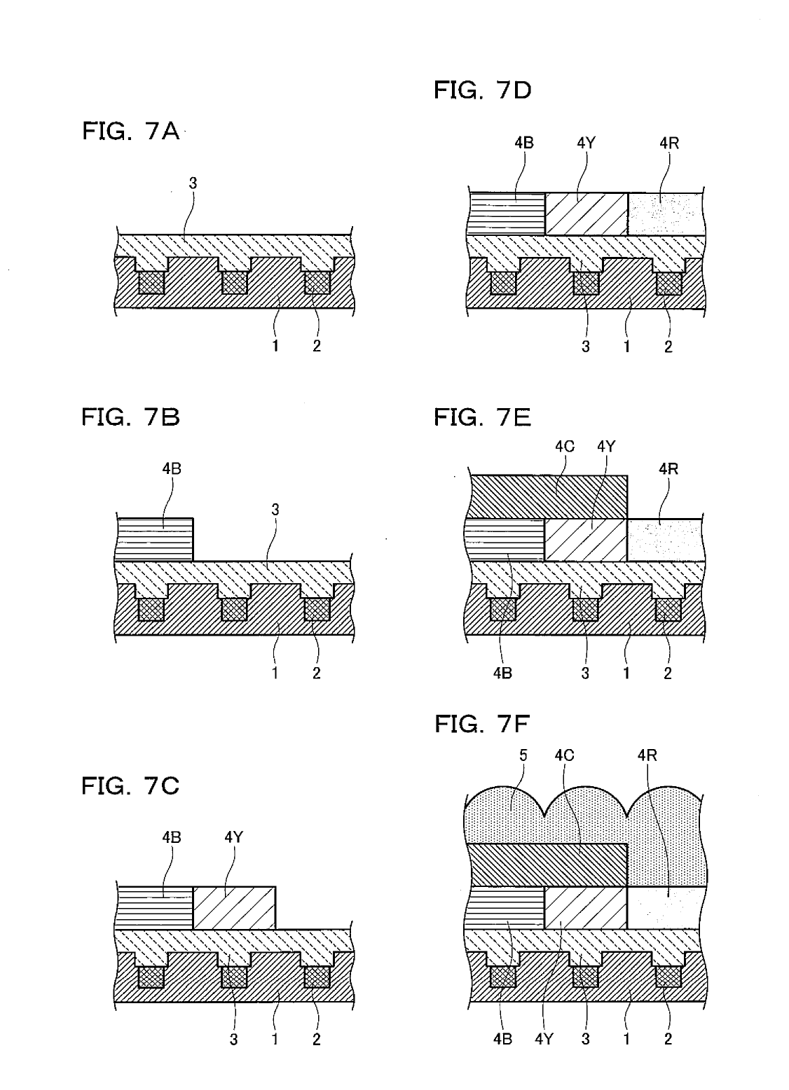

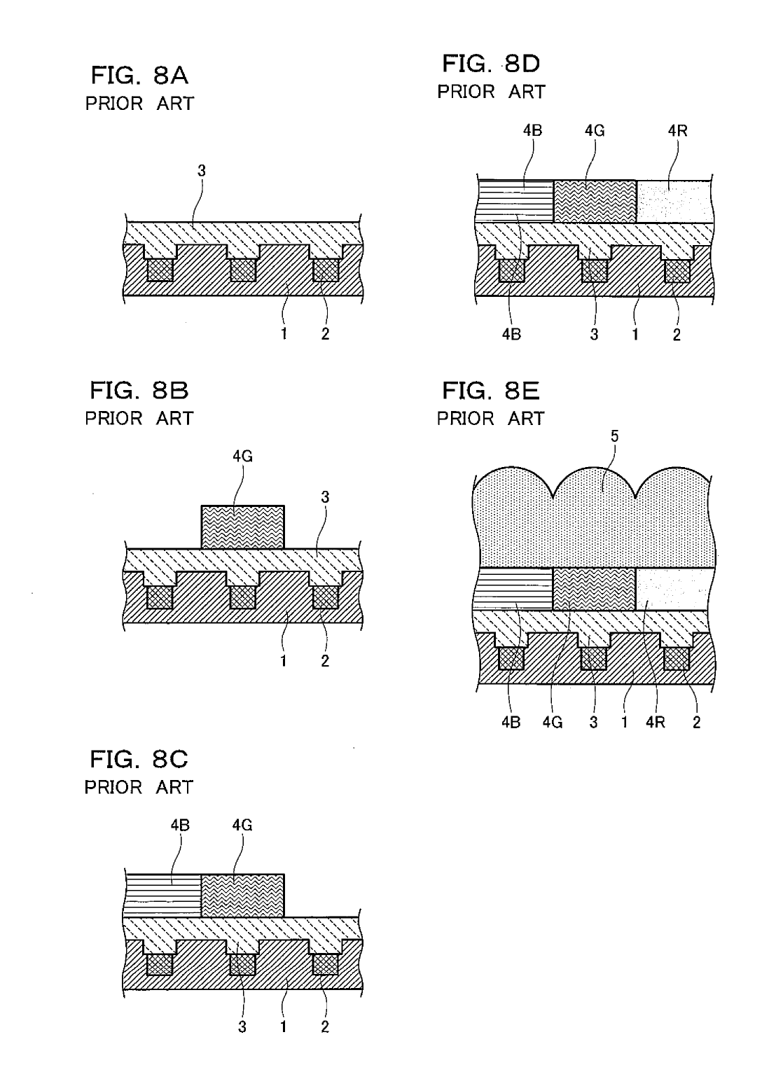

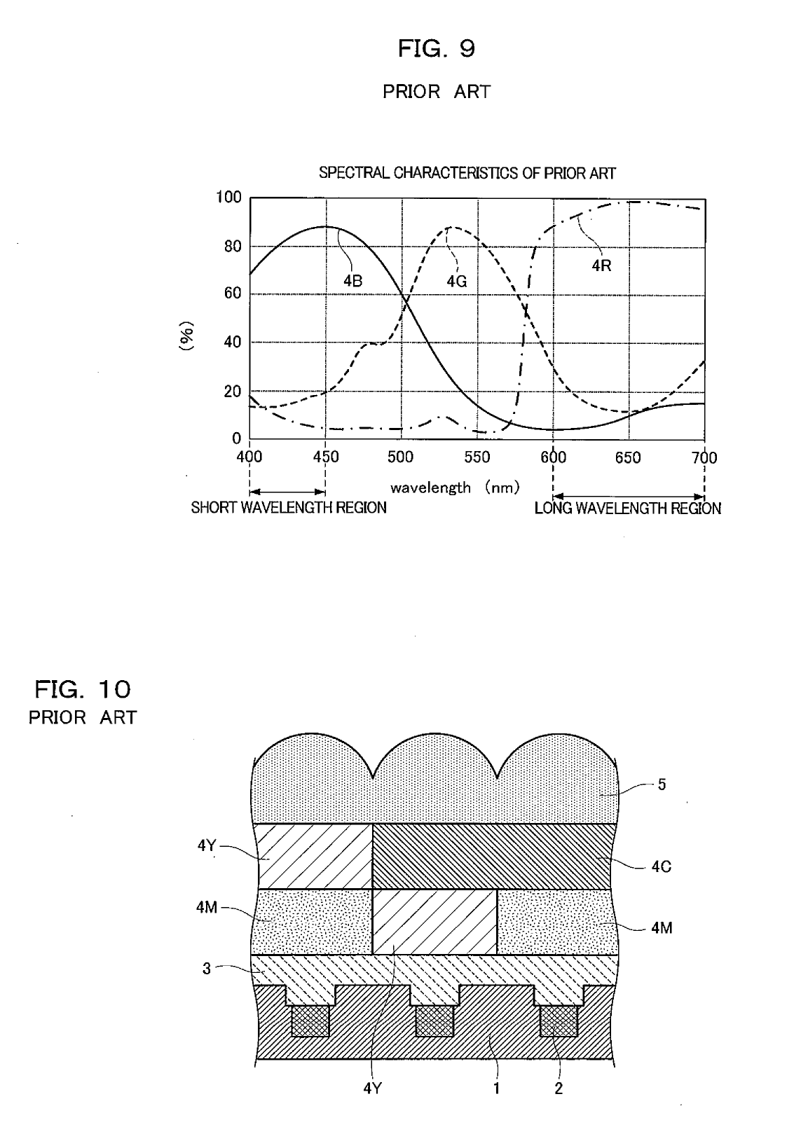

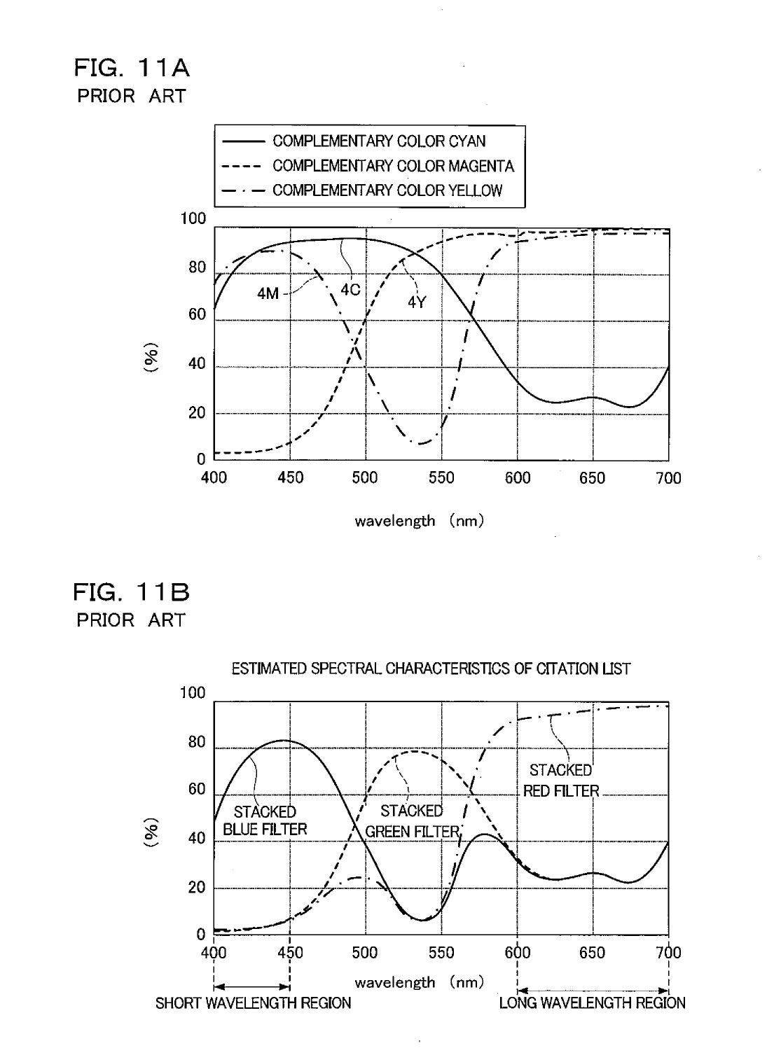

FIGS. 7A, 7B, 7C, 7D, 7E, and 7F are process sectional views showing a method of manufacturing a solid-state image device according to a sixth embodiment.

As shown in FIG. 7F, the solid-state image device is made up of a solid-state image element substrate 1; a plurality of light receiving portions 2 that are photodiodes formed in the solid-state image element substrate 1; an acrylic flat film 3 formed on the light receiving portions 2; a blue filter 4B, a yellow filter 4Y, and a red filter 4R that are formed on the acrylic flat film 3; a cyan filter 4C formed on the blue filter 4B and the yellow filter 4Y; and a plurality of microlenses 5 that are placed above the respective light receiving portions 2 and condense incident light onto the light receiving portions 2 placed below the respective microlenses 5. In the solid-state image device, it is necessary to reproduce primary colors that are red, green, and blue. The cyan filter 4C is stacked on the blue filter 4B to reproduce blue, the cyan filter 4C is stacked on the yellow filter 4Y to reproduce green, and the red filter 4R is formed alone to reproduce red.

In this configuration, the blue filter 4B and the cyan filter 4C are stacked to reproduce blue. Thus as shown in FIG. 2A, the spectral characteristics of the stacked filters are determined by the spectral characteristics of the blue filter 4B and the cyan filter 4C and it is possible to suppress an increase in the spectral characteristics of blue of the stacked color filters in a long wavelength region around 600 nm to 700 nm where the spectral characteristics of blue considerably affect the spectral characteristics of red, as compared with the case where the yellow filter 4Y is stacked on a magenta filter 4M to reproduce blue. It is therefore possible to improve the color reproducibility of red.

FIGS. 7A, 7B, 7C, 7D, 7E, and 7F show a method of forming the solid-state image device according to the present embodiment.

As shown in FIG. 7A, acrylic resin is applied by spin coating over the uneven surface of a layer made up of the solid-state image element substrate 1 and the light receiving portions 2 for converting incident light into an electric signal, and then the acrylic resin is dried by heating to form the acrylic flat film 3.

Next, as shown in FIG. 7B, a color resist of blue is applied by spin coating with a thickness of 0.5 μm to 2.0 μm on the acrylic flat film 3. After that, the color resist of blue is irradiated with ultraviolet light including g-rays (wavelength of 436 nm) and i-rays (wavelength of 365 nm) to form a blue pixel pattern with a photomask. Further, the color resist is patterned in a divided manner and then is dried by heating at 200° C. to 250° C. to form the blue filter 4B.

Next, as shown in FIG. 7C, a color resist of yellow is applied by spin coating with a thickness of 0.5 μm to 2.0 μm on the acrylic flat film 3 and the blue filter 4B. After that, the color resist of yellow is irradiated with ultraviolet light including g-rays (wavelength of 436 nm) and i-rays (wavelength of 365 nm) to form a green pixel pattern with a photomask. Further, the color resist is patterned in a divided manner and then is dried by heating at 200° C. to 250° C. to form the yellow filter 4Y. At this point, the yellow filter 4Y is desirably as thick as the blue filter 4B.

Next, as shown in FIG. 7D, a color resist of red is applied by spin coating with a thickness of 0.5 μm to 2.0 μm on the acrylic flat film 3, the blue filter 4B, and the yellow filter 4Y. After that, the color resist of red is irradiated with ultraviolet light including g-rays (wavelength of 436 nm) and i-rays (wavelength of 365 nm) to form a red pixel pattern with a photomask. Further, the color resist is patterned in a divided manner and then is dried by heating at 200° C. to 250° C. to form the red filter 4R. At this point, the red filter 4R is desirably as thick as the blue filter 4B and the yellow filter 4Y.

Next, as shown in FIG. 7E, a color resist of cyan is applied by spin coating with a thickness of 0.5 μm to 2.0 μm on the blue filter 4B, the yellow filter 4Y, and the red filter 4R. After that, the color resist of cyan is irradiated with ultraviolet light including g-rays (wavelength of 436 nm) and i-rays (wavelength of 365 nm) to form blue and green pixel patterns with a photomask. Further, the color resist is patterned in a divided manner and then is dried by heating at 200° C. to 250° C. to form the cyan filter 4C.

The color resist may be one of a negative resist and a positive resist or one of a pigment resist and a dye resist.

The color filters may be formed in any order as long as the primary blue filter 4B and the complementary cyan filter 4C are stacked on top of each other and the complementary yellow filter 4Y and the complementary cyan filter 4C are stacked on top of each other.

The present embodiment described an example in which the cyan filter used for reproducing blue and the cyan filter used for reproducing green are formed at the same time. The cyan filters may be separately formed.

Finally, as shown in FIG. 7F, a synthetic resin film made of, e.g., acrylic resin is applied by spin coating over the cyan filter 4C and the red filter 4R, and then the synthetic resin film is dried at low temperature. After that, the synthetic resin film is irradiated with ultraviolet light including g-rays (wavelength of 436 nm) and i-rays (wavelength of 365 nm) to form a predetermined pattern with a photomask. Further, the synthetic resin film is patterned into separate pixels. Next, the overall synthetic resin film is exposed to ultraviolet rays and the transmittance of an overall visible light region is improved to at least 90%. After that, heating and melting (reflow) are performed over the synthetic resin film and the synthetic resin film is thermally deformed into dome shapes, each projecting upward with a desired curvature, so that the microlenses 5 are formed.

### INDUSTRIAL APPLICABILITY

The present invention is useful for, e.g., a solid-state image device that is provided with color filters and can suppress an increase in spectral characteristics and improve the color reproducibility of primary color filters.

What is claimed is:

1. A solid-state image device comprising:
a plurality of photodiodes formed on a solid-state image element substrate;
a color filter used for reproducing red and formed on the photodiode receiving red light, out of the plurality of photodiodes;
a color filter used for reproducing green and formed on the photodiode receiving green light, out of the plurality of photodiodes; and
a color filter used for reproducing blue and formed on the photodiode receiving blue light, out of the plurality of photodiodes,
wherein at least one of the color filter used for reproducing red, the color filter used for reproducing green, and the color filter used for reproducing blue is formed by stacking at least two of a red filter, a green filter, a blue filter, a cyan filter, and a yellow filter.

2. The solid-state image device according to claim 1, wherein the color filter used for reproducing red is formed by stacking the red filter and a first yellow filter,
the color filter used for reproducing green is formed by stacking a second yellow filter and a first cyan filter, and
the color filter used for reproducing blue is formed by stacking a second cyan filter and the blue filter.

3. The solid-state image device according to claim 1, wherein the color filter used for reproducing red is formed by stacking the red filter and a first yellow filter,
the color filter used for reproducing green is formed by stacking a second yellow filter and the cyan filter, and
the color filter used for reproducing blue is formed by stacking the blue filter alone.

4. The solid-state image device according to claim 1, wherein the color filter used for reproducing red is formed by stacking the red filter and the yellow filter,
the color filter used for reproducing green is formed by stacking the green filter alone, and
the color filter used for reproducing blue is formed by stacking the cyan filter and the blue filter.

5. The solid-state image device according to claim 1, wherein the color filter used for reproducing red is formed by stacking the red filter and the yellow filter,
the color filter used for reproducing green is formed by stacking the green filter alone, and
the color filter used for reproducing blue is formed by stacking the blue filter alone.

6. The solid-state image device according to claim 1, wherein the color filter used for reproducing red is formed by stacking the red filter alone,
the color filter used for reproducing green is formed by stacking the green filter alone, and
the color filter used for reproducing blue is formed by stacking the cyan filter and the blue filter.

7. The solid-state image device according to claim 1, wherein the color filter used for reproducing red is formed by stacking the red filter alone,
the color filter used for reproducing green is formed by stacking the yellow filter and a first cyan filter, and
the color filter used for reproducing blue is formed by stacking a second cyan filter and the blue filter.

8. The solid-state image device according to claim 2, wherein the first yellow filter and the second yellow filter are formed in a same layer.

9. The solid-state image device according to claim 3, wherein the first yellow filter and the second yellow filter are formed in a same layer.

10. The solid-state image device according to claim 2, wherein the first cyan filter and the second cyan filter are formed in a same layer.

11. The solid-state image device according to claim 7, wherein the first cyan filter and the second cyan filter are formed in a same layer.
